(19) United States
(12) Patent Application Publication
(10) Pub. No.: US 2025/0223698 A1
(43) Pub. Date: Jul. 10, 2025

(54) GAS MANIFOLD AND ASSEMBLY AND SYSTEM INCLUDING SAME

(71) Applicant: ASM IP Holding B.V., Almere (NL)

(72) Inventors: Qi Qi, Phoenix, AZ (US); Rajmohan Muthaiah, Phoenix, AZ (US); Shubham Garg, Gilbert, AZ (US); Daniel Maurice, Phoenix, AZ (US); Madhan Kumar Arulanandam, Tempe, AZ (US); Nirmal Gokuldas Waykole, Tempe, AZ (US)

(21) Appl. No.: 19/007,858

(22) Filed: Jan. 2, 2025

Related U.S. Application Data
(60) Provisional application No. 63/617,914, filed on Jan. 5, 2024.

(51) Int. Cl. C23C 16/455

(52) U.S. Cl. CPC C23C 16/45561; C23C 16/45591

(57) ABSTRACT

Apparatus for providing gas to a reaction chamber, reactor systems including the apparatus, and methods of using the apparatus and systems are disclosed. The systems and methods as described herein can be used to, for example, provide a mixture of two or more precursors to a reaction chamber with desired flow distribution.

### CROSS-REFERENCE TO RELATED APPLICATIONS

This application is a nonprovisional of, and claims priority to and the benefit of, U.S. Provisional Patent Application No. 63/617,914, filed Jan. 5, 2024 and entitled “GAS MANIFOLD AND ASSEMBLY AND SYSTEM INCLUDING SAME,” which is hereby incorporated by reference herein.

### FIELD OF INVENTION

The present disclosure generally relates to gas-phase reactor systems and components thereof. More particularly, the disclosure relates to apparatus suitable for providing one or more gases to a reaction chamber of a reactor system.

### BACKGROUND OF THE DISCLOSURE

Gas-phase reactors, such as chemical vapor deposition (CVD), plasma-enhanced CVD (PECVD), atomic layer deposition (ALD), and the like can be used for a variety of applications, including depositing and etching materials on a substrate surface. For example, gas-phase reactors can be used to deposit and/or etch layers on a substrate to form semiconductor devices, flat panel display devices, photovoltaic devices, microelectromechanical systems (MEMS), and the like.

A typical gas-phase reactor system includes one or more reactors, each reactor including one or more reaction chambers; one or more precursor and/or reactant gas sources fluidly coupled to the reaction chamber(s); one or more carrier and/or purge gas sources fluidly coupled to the reaction chamber(s); one or more gas distribution systems to deliver gases (e.g., the precursor/reactant gas(es) and/or carrier or purge gas(es)) to a surface of a substrate within a reaction chamber; and at least one exhaust source fluidly coupled to the reaction chamber(s).

In some processes carried out in reaction chambers, it may be desirable to provide two or more gases to the reaction chamber at the same time or overlapping in time. For example, two or more gases can be separately provided to a reaction chamber at the same time or overlapping in time. While such apparatus may be suitable for some applications, providing gases separately to the reaction chamber may result in undesired variability in a process. Further, it may be desirable to provide a desired flow pattern of a gas to a gas distribution device to achieve a desired flow pattern of the gas across a surface of a substrate. Accordingly, improved apparatus for providing a gas mixture and/or a desired flow pattern of a gas to a gas distribution device and/or a reaction chamber are desired.

Any discussion of problems and solutions involved in the related art has been included in this disclosure solely for the purposes of providing a context for the present disclosure, and should not be taken as an admission that any or all of the discussion was known at the time the invention was made.

### SUMMARY OF THE DISCLOSURE

Various embodiments of the present disclosure relate to apparatus for providing

a gas mixture to a reactor or a reaction chamber, to assemblies and systems including the apparatus, and to methods of using the apparatus, assemblies, and systems. The apparatus, assemblies, and systems can be used in connection with a variety of applications, including, for example, the manufacturing of electronic devices. While the ways in which various embodiments of the present disclosure address drawbacks of prior apparatus, assemblies, and systems are discussed in more detail below, in general, various embodiments of the disclosure provide improved apparatus (e.g., a gas manifold), assemblies, and systems and methods suitable for providing a mixture of two or more gases to a reaction chamber. Exemplary apparatus can, for example, reduce the time scale for diffusion of gas, thereby improving mixing of gases and/or reducing an amount of time to mix gases prior to entering the reaction chamber. Further examples of the disclosure provide improved apparatus and methods for providing pulses of mixed gas.

In accordance with at least one embodiment of the disclosure, a gas manifold is provided. An exemplary gas manifold includes a body comprising a top section and a bottom section, a channel spanning along an axis within the body and between the top section and an opening in the bottom surface, a first conduit extending from the top surface and fluidly coupled to the channel, a second conduit extending substantially radially from the axis and fluidly coupled to the channel; and a flow regulator within the bottom section. The flow regulator is configured to change a flow direction of gas received from the first conduit and gas received from the second conduit. In accordance with examples of the disclosure, the flow regulator comprises a plurality of fins extending inward from an interior wall of the channel. In accordance with further examples, the flow regulator comprises a helical section. In accordance with further examples, the flow regulator comprises a plurality of deflectors extending from an interior surface of the channel toward the axis. In accordance with yet further examples, the flow regulator comprises a first body spanning a first cross-section of the channel and comprising a first plurality of holes through the first body. In accordance with further examples, the flow regulator further comprises a second body spanning a second cross section of the channel and comprising a second plurality of holes through the second body. And, in accordance with yet further examples, the flow regulator comprises a plate having an opening therethrough, wherein the opening comprises a first exterior section, a second exterior section, and an interior section connecting the first exterior section and the second exterior section, wherein a cross section of the interior section is less than a cross section of the first exterior section and is less than a cross section of the second exterior section.

In accordance with further embodiments, an assembly including a gas manifold and a gas distribution device fluidly coupled to the gas manifold is provided. The gas manifold can be or include a gas manifold as described above or elsewhere herein. The gas distribution device can be or include, for example, a showerhead device or portion thereof.

In accordance with yet additional embodiments of the disclosure, a reactor system is provided. An exemplary reactor system includes a reaction chamber, a gas distribution device, and a manifold, such as a manifold described herein.

In accordance with additional embodiments of the disclosure, a method controlling a gas flow to a reaction chamber using an apparatus, assembly, and/or system as described herein is disclosed.

These and other embodiments will become readily apparent to those skilled in the art from the following detailed description of certain embodiments having reference to the attached figures; the invention not being limited to any particular embodiment(s) disclosed.

BRIEF DESCRIPTION OF THE DRAWING FIGURES

A more complete understanding of exemplary embodiments of the present disclosure can be derived by referring to the detailed description and claims when considered in connection with the following illustrative figures.

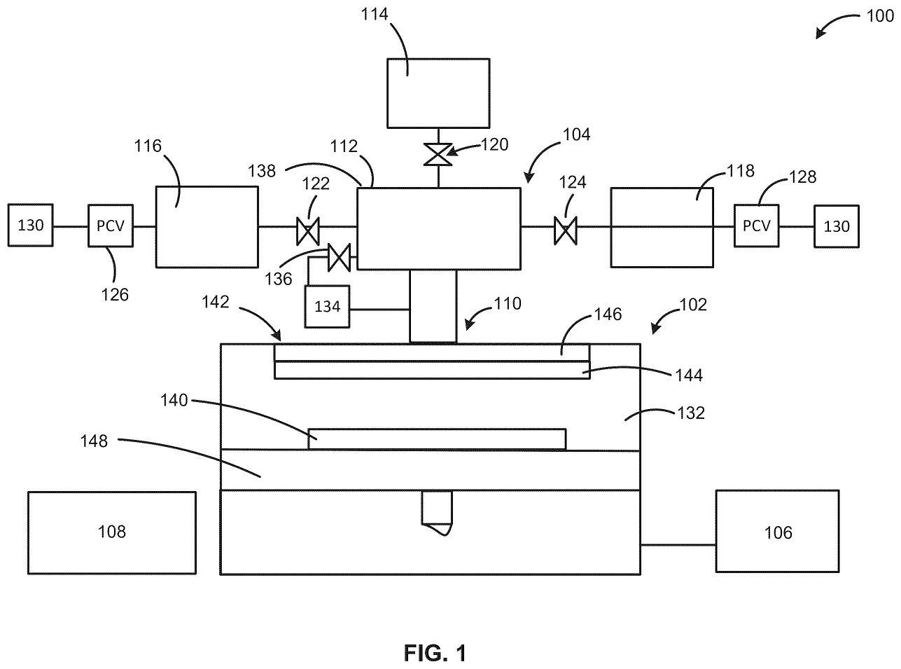

FIG. 1 illustrates a reactor system including a gas manifold in accordance with at least one embodiment of the disclosure.

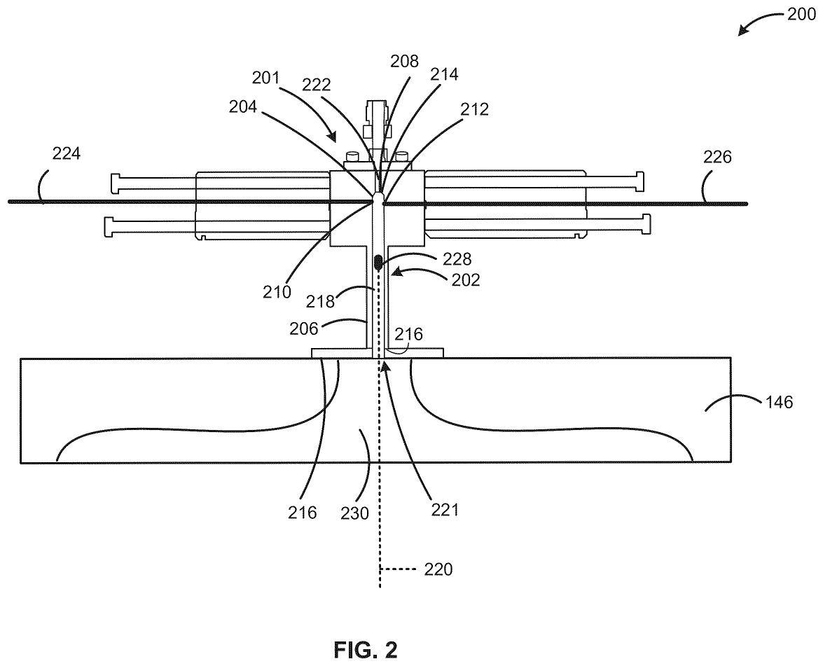

FIG. 2 illustrates an assembly in accordance with examples of the disclosure.

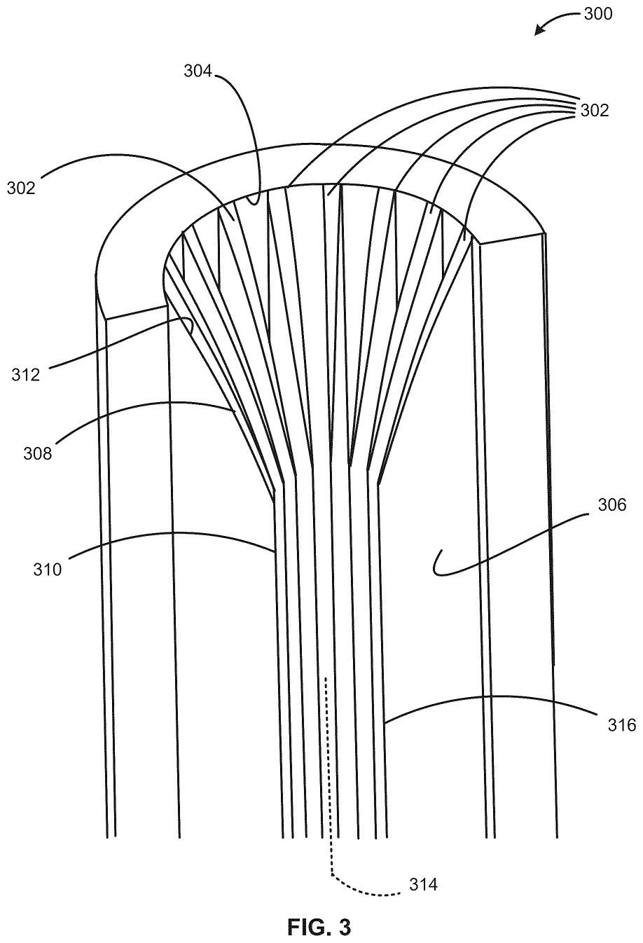

FIG. 3 illustrates a portion of a gas manifold and a flow regulator in accordance with the disclosure.

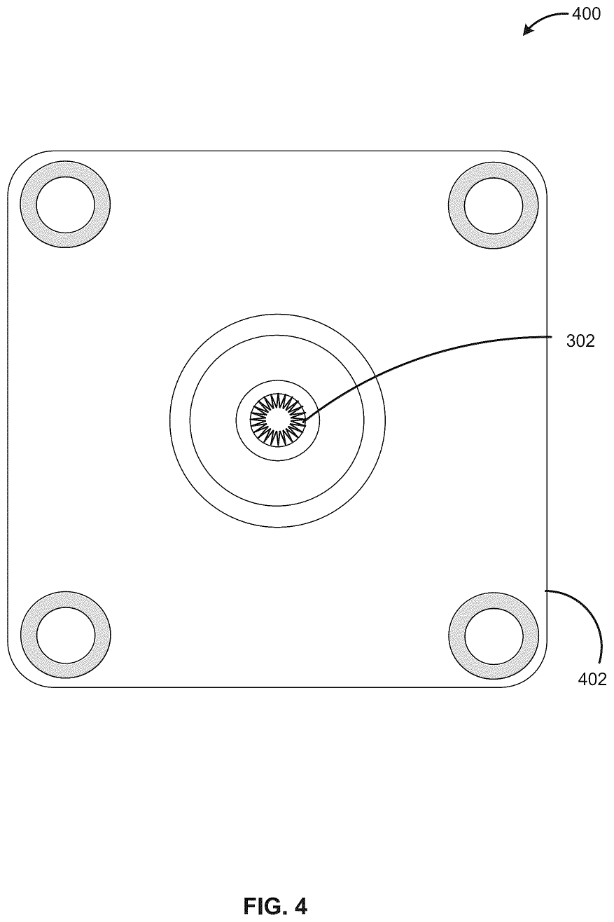

FIG. 4 illustrates a bottom view of an assembly in accordance with examples of the disclosure.

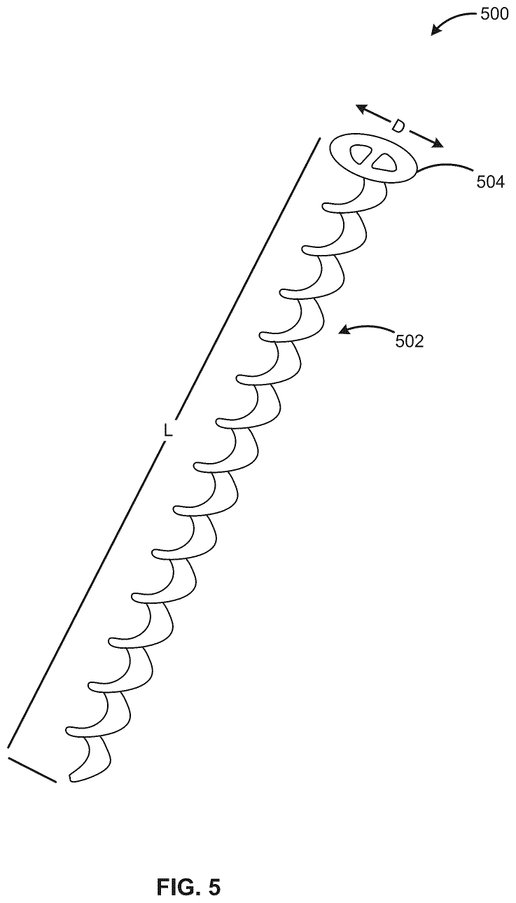

FIG. 5 illustrates a flow regulator in accordance with examples of the disclosure.

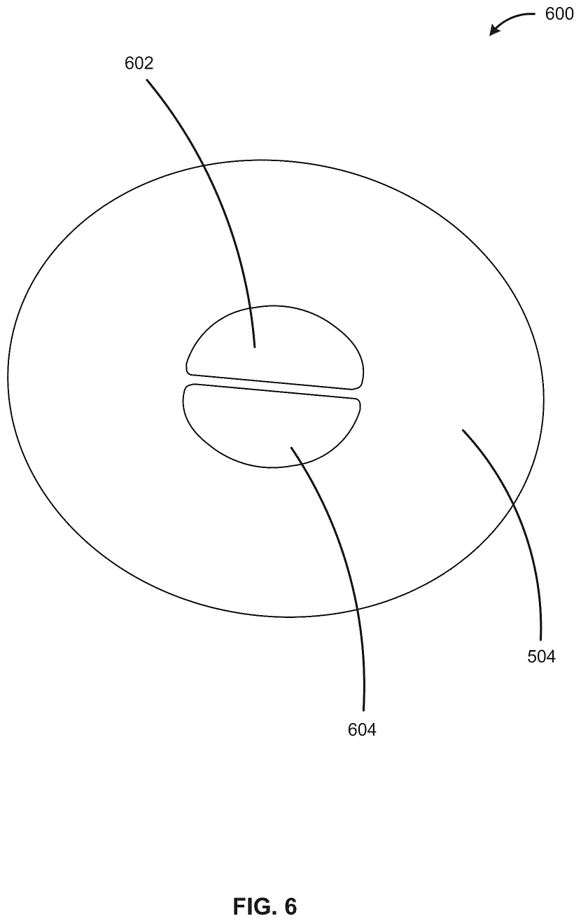

FIG. 6 illustrates a portion of a flow regulator in accordance with examples of the disclosure.

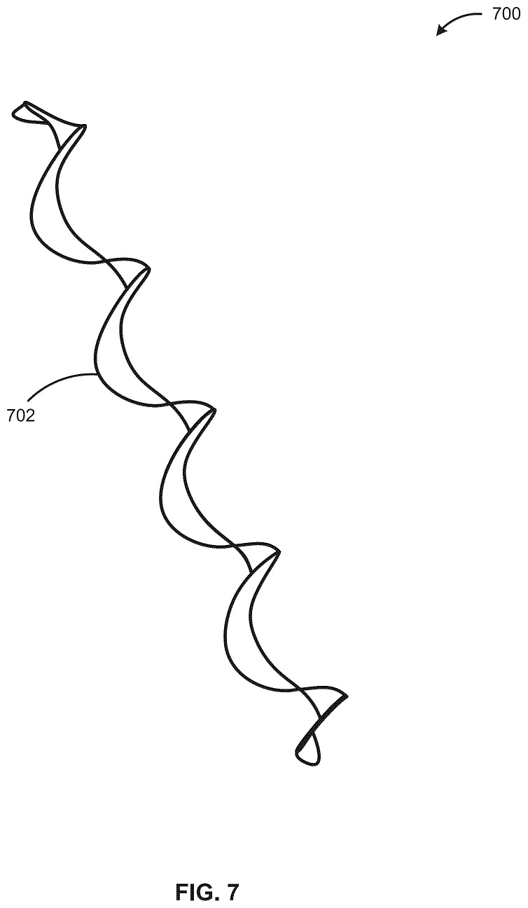

FIG. 7 illustrates a portion of a flow regulator in accordance with additional examples of the disclosure.

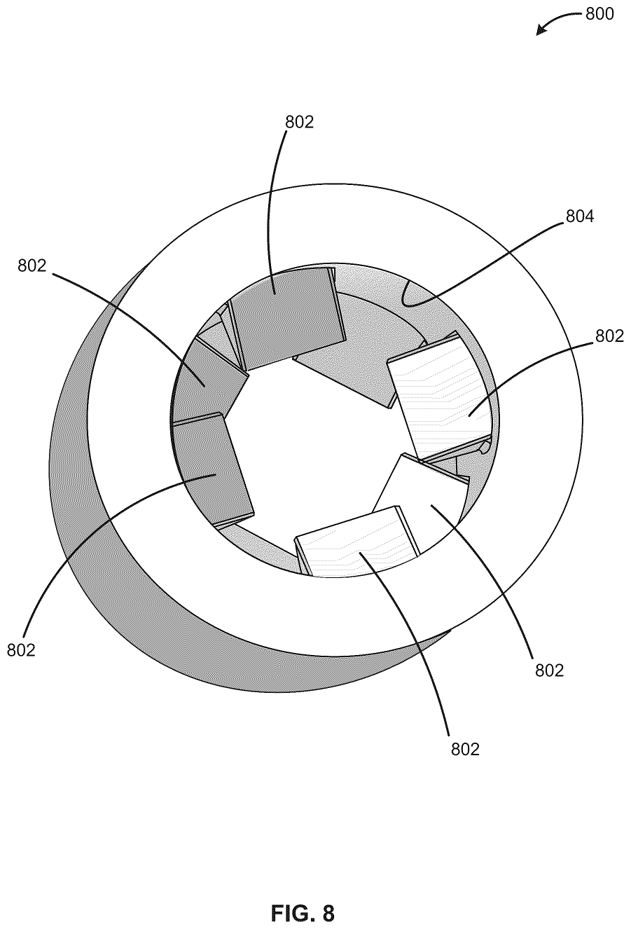

FIG. 8 illustrates a flow regulator in accordance with additional examples of the disclosure.

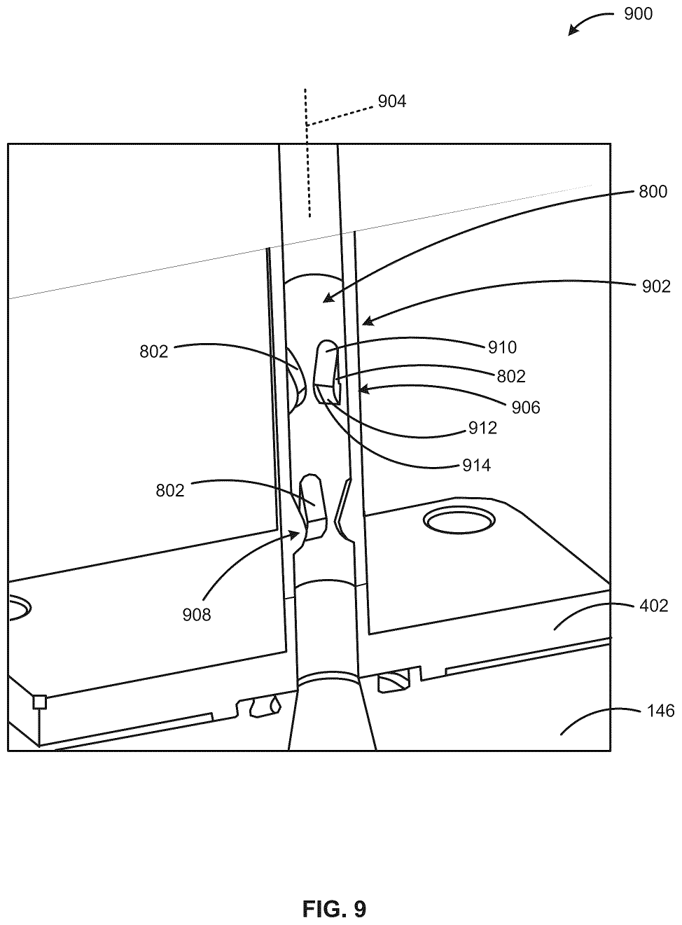

FIG. 9 illustrates a flow regulator in accordance with yet additional examples of the disclosure.

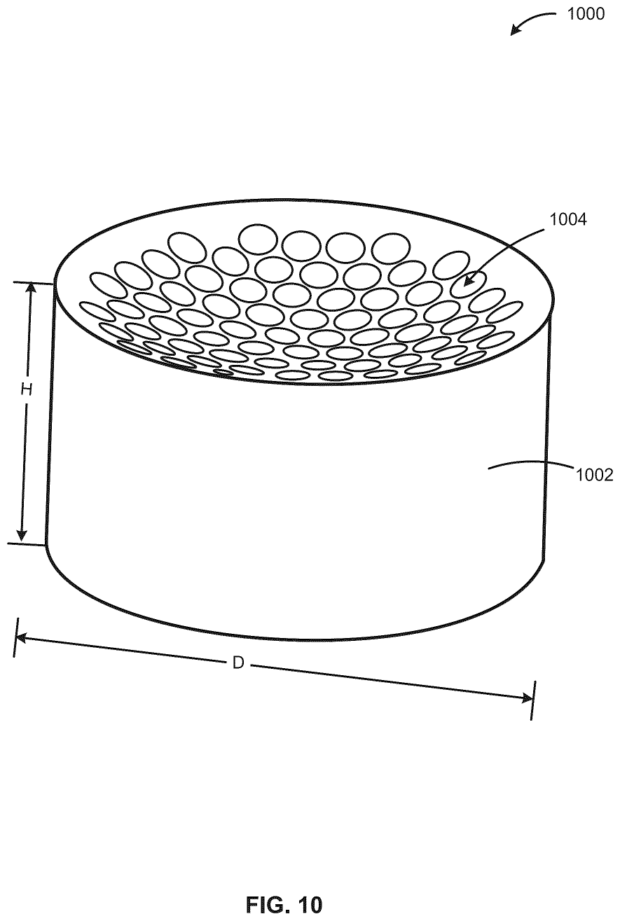

FIG. 10 illustrates a flow regulator in accordance with yet additional examples of the disclosure.

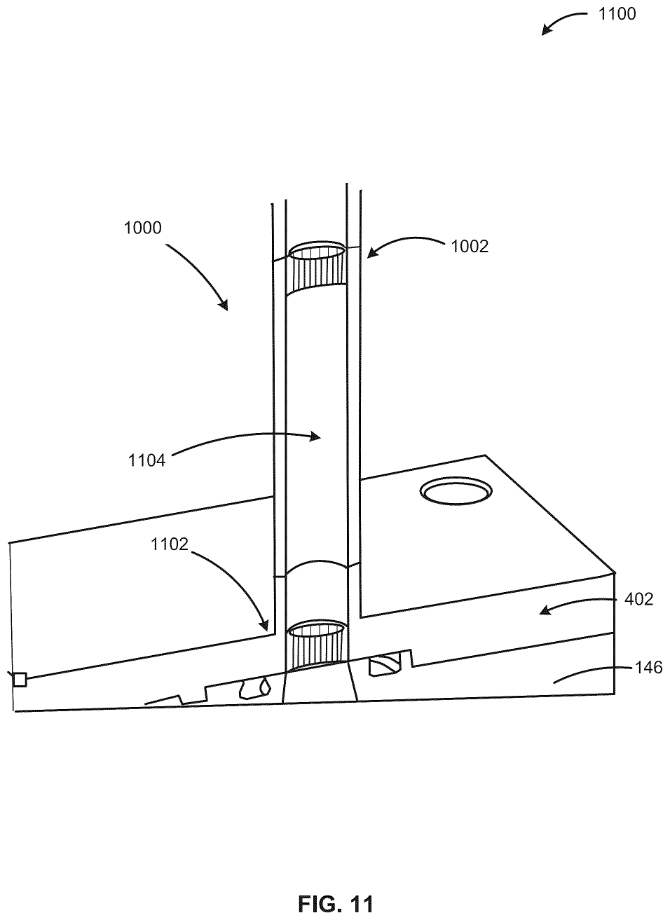

FIG. 11 illustrates an assembly in accordance with additional examples of the disclosure.

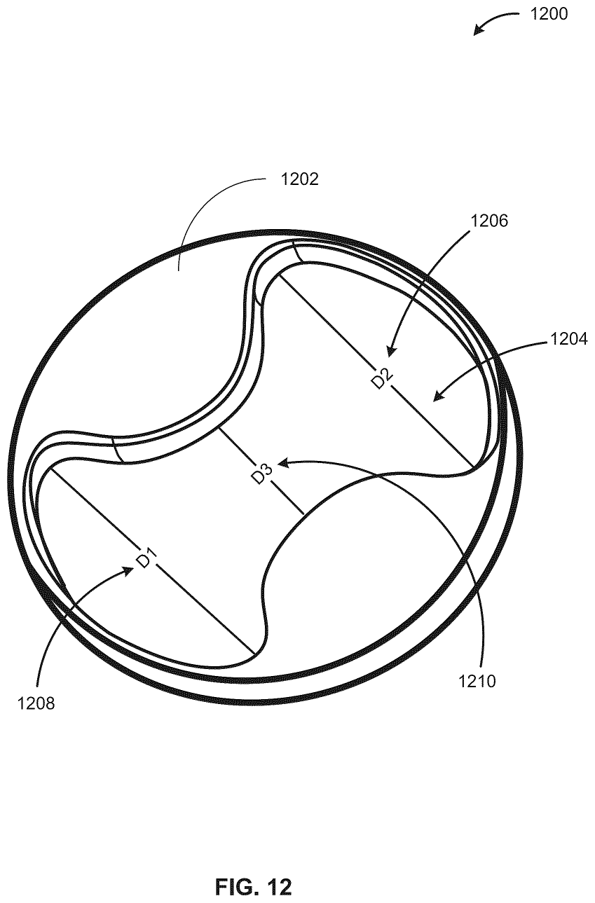

FIG. 12 illustrates a flow regulator in accordance with yet additional examples of the disclosure.

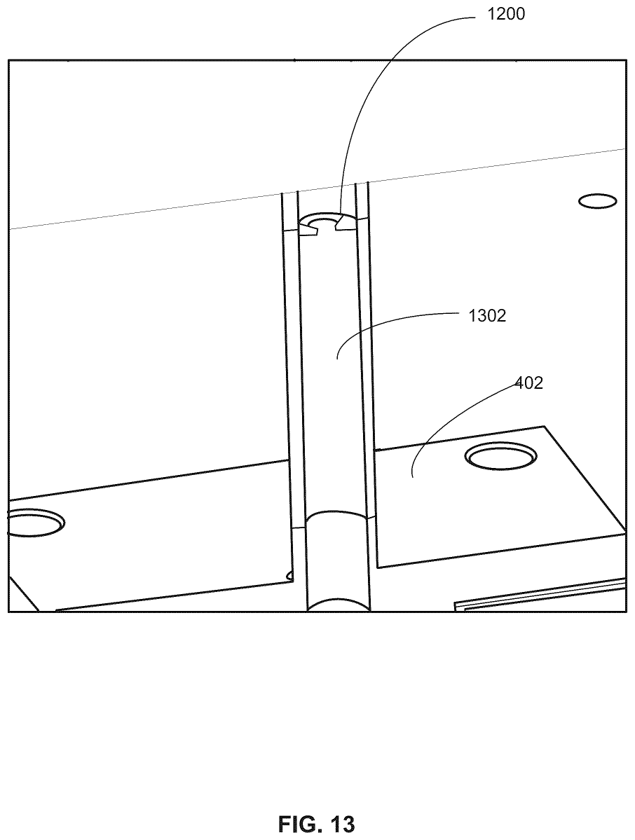

FIG. 13 illustrates an assembly in accordance with additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below.

The present disclosure generally relates to manifolds, assemblies including a manifold, and reactor systems including an assembly or manifold. The manifolds, assemblies, and systems as described herein can be used to process substrates, such as semiconductor wafers, to form, for example, electronic devices. By way of examples, the systems and methods described herein can be used to form or grow multi-component layers. By way of particular examples, the manifolds, assemblies, and systems can be used in thermal atomic layer deposition (ALD) processes.

In this disclosure, gas can include material that is a gas at normal temperature and pressure (NTP), a vaporized solid and/or a vaporized liquid, and can be constituted by a single gas or a mixture of gases, depending on the context. A gas other than a process gas, i.e., a gas introduced without passing through a gas distribution assembly, other gas distribution device, or the like, can be used for, e.g., sealing the reaction space, and can include a seal gas, such as a rare gas.

The term precursor can refer to a compound that participates in the chemical reaction that produces another compound. The term reactant can be used interchangeably with the term precursor. The term inert gas can refer to a gas that does not take part in a chemical reaction and/or does not become a part of a layer to an appreciable extent. Exemplary inert gases include helium and argon and any combination thereof. In some cases, molecular nitrogen and/or hydrogen can be an inert gas. A carrier gas can be or include an inert gas.

As used herein, the term substrate may refer to any underlying material or materials that may be used to form, or upon which, a device, a circuit, or a film may be formed. A substrate can include a bulk material, such as silicon (e.g., single-crystal silicon), other Group IV materials, such as germanium, or compound semiconductor materials, such as GaAs, and can include one or more layers overlying or underlying the bulk material. Further, the substrate can include various topologies, such as recesses, lines, and the like formed within or on at least a portion of a layer of the substrate.

The term cyclic deposition process or cyclical deposition process can refer to the sequential introduction of precursors (and/or reactants) into a reaction chamber to deposit a layer over a substrate and includes processing techniques, such as ALD, cyclical chemical vapor deposition (cyclical CVD), and hybrid cyclical deposition processes that include an ALD component and a cyclical CVD component. The process may comprise a purge step between introducing precursors. In some cases, one or more reactants and/or precursors can be continuously provided to the reaction chamber and one or more other reactants and/or precursors can be pulsed to the reaction chamber.

Further, in this disclosure, any two numbers of a variable can constitute a workable range of the variable, and any ranges indicated may include or exclude the endpoints. Additionally, any values of variables indicated (regardless of whether they are indicated with “about” or not) may refer to precise values or approximate values and include equivalents, and may refer to average, median, representative, majority, or the like. Further, in this disclosure, the terms “including,” “constituted by” and “having” can refer independently to “typically or broadly comprising,” “comprising,” “consisting essentially of,” or “consisting of” in some embodiments. “Substantially” can mean within about ±10 or ±5 relative or absolute percent. Substantially flat can mean a surface that can deviate ±10 or ±5 relative or absolute percent from a level plane. The term comprising includes consisting essentially of and consisting of. In this disclosure, any defined meanings do not necessarily exclude ordinary and customary meanings in some embodiments.

Turning now to the figures, FIG. 1 illustrates a reactor system 100 in accordance with at least one embodiment of the disclosure. Reactor system 100 includes a reaction chamber 102, an apparatus 104 for providing a gas mixture to the reaction chamber 102, a vacuum source 106, and a controller 108.

Reaction chamber 102 can be or include a reaction chamber suitable for gas-phase reactions. Reaction chamber 102 can be formed of suitable material, such as quartz, metal, or the like, and can be configured to retain one or more substrates for processing. Reactor system 100 can include any suitable number of reaction chambers 102 and can optionally include one or more substrate handling systems.

Reaction chamber 102 can be configured as a CVD reactor, a cyclical deposition process reactor (e.g., a cyclical CVD reactor), an ALD reactor, a PEALD reactor, an etch reactor, a treatment reactor, a surface clean reactor, or the like, any of which may include plasma apparatus, such as direct and/or remote plasma apparatus.

Apparatus 104 for providing a gas mixture to a reaction chamber includes a gas injection port 110, a mixing device 112, a first gas source 114, a second gas source 116, a third gas source 118, a first gas valve 120, a second gas (e.g., pulse) valve 122, a third gas (e.g., pulse) valve 124. Apparatus 104 and/or reactor system 100 can also include a first pressure flow control valve 126, a second pressure flow control valve 128, and one or more carrier gas sources 130. Reactor system 100 and/or apparatus 104 can suitably include additional gas sources and respective lines and valves. Apparatus 104 can be used to mix gases from two or more gas sources 114-118 by providing pulses of the two or more gases to mixing device 112, which, in this illustrated example, is downstream of the pulsing valve(s). Apparatus 104 allows flexibility in timing (e.g., one gas can start before or after other gas flows to mixing device 112). Further, apparatus 104 can easily transition to a single gas injection system, without delay.

Gas injection port 110 can include tubing, an opening, or the like to provide a gas mixture to a reaction zone 132 of reaction chamber 102. Gas injection port 110 can be integrated into reaction chamber 102 or can be separate.

Mixing device 112 is configured to receive two or more gases-e.g., from two or more of first gas source 114, second gas source 116, and third gas source 118 prior to entering reaction chamber 102. As illustrated, mixing device 112 can be upstream of and in fluid communication with gas injection port 110. Mixing device 112 can include a volume that is larger than a volume of gas injection port 110. By way of example, a volume of mixing device 112 can range from about 5 to about 50 cc. A configuration of mixing device 112 can vary according to application. Mixing device 112 can include a torturous pathway to facilitate desired mixing and flow of a gas mixture. In some cases, mixing device 112 can include a housing 138, which can be, for example, substantially a hollow cylinder. Mixing device 112 can be referred to as a manifold. Exemplary manifolds suitable for mixing device 112 are described in more detail below in connection with FIGS. 2-13.

First gas source 114, second gas source 116, and third gas source 118 can each include a vessel and a gas stored within the respective vessel. By way of example, first gas source 114 can include a vessel and inert gas; second gas source 116 can include a vessel and a first precursor; and third gas source 118 can include a vessel and a second precursor. Reactor system 100 or apparatus 104 for providing a gas mixture to a reaction chamber can include a reactant source 134 that can be coupled to gas injection port 110 and/or to mixing device 112. Reactant source 134 can include one or more reactant vessels and one or more reactant sources, such as, for example, one or more of an oxygen reactant, a nitrogen reactant, and/or a carbon reactant.

Two or more or each of second gas source 116, third gas source 118, and optionally other gas source(s) can be coupled to mixing device 112 using a pulse valve, such as pulse valves 122, 124. Additional gas sources can similarly be coupled to mixing device 112. Apparatus 104 and/or reactor system 100 can additionally include a pulse valve 136 between reactant source 134 and gas injection port 110 and/or mixing device 112. Pulse valves 122, 124, 136 can be used to provide a desired amount (pulse) of a gas to mixing device 112 (or gas injection port 110). By way of examples, one or more of gas pulse valves 122, 124, 136 or other pulse valves described herein can comprise a pneumatic or electric solenoid valve.

As further illustrated, a carrier gas from a carrier gas source 130 (which may include one or more carrier gas sources) can be used to supply one or more of the first, second, and/or another precursor to reaction chamber 102 and/or additional gases as described herein. In the illustrated example, carrier gas source 130 is coupled to a first pressure flow control valve 126 to supply a desired concentration of the first precursor to first gas pulse valve 120; carrier gas source 130 is coupled to a second pressure flow control valve 128 to supply a desired concentration of the second precursor to second gas pulse valve 122; and an inert gas source 114 is coupled to a valve 120 to supply a desired concentration of inert gas to mixing device 112. Pressure control valves 126, 128 can be used to maintain a steady/desired pressure within the respective first vessel and second vessel to provide a controlled flow of the respective first precursor and second precursor and/or other gas. By way of example, a pressure control valve can be or include a pressure flow controller or mass flow controller.

Vacuum source 106 can include, for example, one or more vacuum sources. Exemplary vacuum sources include one or more dry vacuum pumps and/or one or more turbomolecular pumps.

Controller 108 can be configured to perform various functions and/or steps as described herein. Controller 108 can include one or more microprocessors, memory elements, and/or switching elements to perform the various functions. Although illustrated as a single unit, controller 108 can alternatively comprise multiple devices. By way of examples, controller 108 can be used to control gas flow to mixing device 112 and a gas mixture from mixing device 112 to vacuum source 106 and/or to reaction chamber 102. In some cases, controller 108 can be used to pulse two or more precursors (e.g., from sources 116, 118) and/or a reactant from reactant source 134 to mixing device 112 and/or gas injection port 110. By way of further examples, controller 108 can independently control each pressure flow control valve 126, 128 and each gas pulse valve 122, 124 to independently provide relative concentrations and relative amounts or ratios (e.g., by mass) of two or more precursors to mixing device 112. In the example illustrated in FIG. 1, controller 108 can be configured to open each pulse valve 122, 124 at substantially the same time (e.g., within about 0.001 or about 0.005 seconds).

In the illustrated example, reactor system 100 includes a susceptor 148 configured to retain a substrate 140. Reactor system 100 also includes a gas distribution system 142 that is or includes a shower assembly that, in turn, includes a showerhead plate 144 and a flow control plate 146. Gas distribution system 142 can provide a gas mixture from mixing device 112 to a top surface of substrate 140.

Turning now to FIG. 2, an exemplary assembly 200, including a gas manifold 201 suitable for use as mixing device 112, is illustrated. Assembly 200 also includes a gas distribution system, such as distribution system 142, which includes flow control plate 146. Gas manifold 201 includes a body 202 including a top section 204 and a bottom section 206. During operation of assembly 200, gases are supplied to gas manifold 201 at inlets 208, 210, 212, which can be coupled to gas sources 114, 116, and 118, respectively.

Top section 204 of body 202 includes a top surface 214. Bottom section 206 includes a bottom surface 216. Gas manifold 201 includes a channel spanning 218 along an axis 220 within the body and between top section 204 and an opening 221 in bottom surface 216.

Gas manifold 201 further includes a first conduit 222 extending from top surface 214. First conduit 222 is fluidly coupled to channel 218. In the illustrated example, gas manifold 201 includes a second conduit 224 extending substantially radially from axis 220 and fluidly coupled to channel 218 and a third conduit 226 extending substantially radially from axis 220 and fluidly coupled to channel 218. Gas manifold 201 can suitably include additional conduits to accommodate additional gases provided to channel 218. As illustrated, each of the first, second, third, and optionally additional conduits can be coupled to or formed within top section 204 of body 202.

In accordance with various examples of the disclosure, gas manifold 201 includes one or more flow regulators 228 within bottom section 206 of body 202. One or more flow regulators 228 can be configured to change a flow direction of gas received from the first conduit, gas received from the second conduit, and/or gas received from the third conduit prior to such gases entering an opening 230 in flow control plate 146.

FIG. 3 illustrates a cross-sectional view of an example of a flow regulator 300 suitable for use as one or more flow regulators 228. FIG. 4 illustrates a bottom view of an assembly including flow regulator 300 and a plate 402 that can couple to flow control plate 146. Flow regulator 300 includes a plurality of fins 302 that extend inward from an

interior wall 304 of a channel 306 (which can be the same or similar to channel 218). Fins 302 can be substantially evenly spaced apart. A number of fins 302 can range from about 1/mm (dia) to about 2/mm (dia) or be about 9 to about 18, where dia represents a diameter or other cross sectional measurement of interior wall 304. A length of each fin can substantially span bottom section 206 and/or be between about cover the full length of tube (e.g., about 136 mm). Fins 302 can be formed of any suitable material, such as metal (e.g., aluminum-6 series, C22 alloy, low carbon stainless steel) or ceramic material. The plurality of fins 302 can be integrally formed within a body, such as body 202 described above, or can be attached—e.g., by welding or brazing.

In the illustrated example, each fin 302 of the plurality of fins comprises a first section 308 and a second section 310. First section 308 comprises an interior angled surface 312 at an angle relative to an axis 314. Axis 314 can be the same as axis 220 described above. The angle relative to an axis 314 can be greater than 0 degrees and less than 90 degrees or between about 15 degrees and about 45 degrees. Second section 310 comprises an interior parallel surface 316 substantially parallel axis 314. A ratio of height (e.g., along axis 314) of first section 308 relative to a height of second section 310 can be, for example, between about 1:20 and about 1:10.

FIG. 5 illustrates another flow regulator 500 in accordance with examples of the disclosure. In accordance with examples of the disclosure, flow regulator 500 can be removably inserted within a channel, such as channel 218, described above. Flow regulator 500 includes a helical section 502 and a plate 504 coupled to helical section 502. FIG. 6 illustrates plate 504 in greater detail.

Helical section 502 can have a length substantially the same as bottom section 206 and/or a length L of between about 30 mm and about 70 mm or about 30 and 70 mm. Helical section 502 can be formed of any suitable material, such as metal (e.g., stainless steel, aluminum or the like) or ceramic (e.g., Al₂O₃). A pitch of a helix of the helical section 502 can be between about 4 mm and about 10 mm or between about 5 and about 8 mm. A cross-sectional width of helical section 502 can be between about 6 mm and about 10 mm or between about 6 mm and about 8 mm.

Plate 504 can include a cross-sectional measurement D that is between about 10 mm and about 15 mm or about 10 and 12 mm. Plate 504 includes one or more openings 602, 604 spanning a height of plate 504. In the illustrated example, each opening 602, 604 is substantially semi-circular. Plate 504 can be formed of the same material as helical section 502.

FIG. 7 illustrates another helical section 702. Helical section 702 can be the same or similar to helical section 502, except a pitch of the helix is between about 4 mm and about 10 mm or between about 6 mm and about 10 mm. Helical section 702 can be attached to a plate, such as plate 504, or can be a standalone flow regulator that is inserted into channel 218. A length of helical section 702 can be the same or similar to the length and/or cross-sectional width of helical section 502 described above.

FIGS. 8 and 9 illustrate another flow regulator 800 in accordance with additional examples of the disclosure. Flow regulator 800 includes a plurality of deflectors 802. Deflectors 802 extend from an interior surface 804 of a channel 902 toward an axis 904 of channel 902. Channel 902 and axis 904 can be the same or similar to channel 218 and axis 220 described above. The plurality of deflectors 802 can include a first set of deflectors 906 at a first height within channel 902 and a second set of deflectors 908 at a second height within the channel, the first height different than the second height. Further, as illustrated in FIGS. 8 and 9, first set of deflectors 906 and second set of deflectors 908 can be (e.g., vertically and rotationally) offset from each other. One or more deflectors 802 (e.g., all of the deflectors) can include a first slanted surface 910 and a second slanted surface 912. First slanted surface 910 and second slanted surface 912 can meet at an edge 914. First slanted surface 910 and second slanted surface 912 can each be relatively flat. A width of first slanted surface 910 can be between about ¼ of a diameter or other cross sectional dimension of channel 902 and about ⅓ of the diameter or other cross sectional dimension of channel 902 or between, for example, about 2 mm and about 3 mm. A width of second slanted surface 912 can be between about same as above. A distance between first set of deflectors 906 and second set of deflectors 908 can be between about 20 mm to 30 mm. First slanted surface 910 can be angled at an angle relative to axis 904, wherein the angle is greater than 0 degrees and less than 90 degrees or between about 15 degrees and about 45 degrees. Second slanted surface 912 can be angled at an angle relative to a line perpendicular to axis 904, wherein the angle is greater than 0 degrees and less than 90 degrees or between about 15 degrees and about 45 degrees.

Deflectors 802 can be formed of any suitable material, such as the ceramic and metal materials noted above. A number of deflectors can be 4, 6, or 9 or, for example, a multiple of 4, which can be divided between first set of deflectors 906 and second set of deflectors 908 in any combination.

FIGS. 10 and 11 illustrate another flow regulator 1000 in accordance with examples of the disclosure. Flow regulator 1000 includes a body 1002 and a plurality of holes 1004 extending through body 1002. As illustrated in FIG. 11, flow regulator 1000 can include two or more bodies. In the example illustrated in FIG. 9, flow regulator 1000 includes a first body 1002 and a second body 1102. Second body 1102 can be the same or similar to first body 1002. A cross-sectional dimension D of body 1002, 1102 can be about the same as an inner diameter of a channel 1104. A height H of each body 1002, 1102 can be between, for example, about 10 mm to about 15 mm. A distance between each body 1002, 1102 can span about a whole tube length (e.g., be about 136 mm). For example, first body 1002 can be at a top of bottom section 206 and second body 1102 can be at a bottom of channel 1104.

Body 1002, 1102 can be formed of any suitable material, such as aluminum-6 series, C22 alloy, low carbon stainless steel, stainless steel, or the like. A number of holes 1004 through body 1002, 1102 can range from about 1:2.3 (dia in mm) to 1:3.5 (dia in mm), where dia represents a (e.g., interior) diameter or other cross sectional measurement of body 1002. The holes can be arranged in rows and columns as illustrated or can be in other configurations. A size of the holes can range from about 0.7 mm to 1.05 mm.

FIGS. 12 and 13 illustrate another flow regulator 1200 in accordance with examples of the disclosure. Flow regulator 1200 comprises a plate 1202 having an opening 1204 therethrough. In the illustrated example, opening 1204 includes a first exterior section 1206, a second exterior section 1208, and an interior section 1210 connecting first exterior section 1206 and second exterior section 1208. A cross section D3 of interior section 1210 is less than a cross section D2 of first exterior section 1206 and D3 is less than a cross section D1 of second exterior section 1208. For example, opening 1204 can be dog bone shaped.

Flow regulator 1200 can have an outer cross-sectional dimension that is substantially the same as an interior cross-sectional dimension of a channel 1302 (which can be the same or similar to channel 218). Flow regulator 1200 can be attached to channel 1302 by brazing or welding. Flow regulator can be formed of any suitable material, such as materials noted above in connection with other flow regulators described above.

The example embodiments of the disclosure described above do not limit the scope of the invention, since these embodiments are merely examples of the embodiments of the invention. For example, although illustrated with three gas sources, examples can include two, four, or more gas sources that may be configured in a manner similar to the illustrated examples. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A gas manifold comprising:
a body comprising a top section and a bottom section, the top section comprising a top surface, and the bottom section comprising a bottom surface;
a channel spanning along an axis within the body and between the top section and an opening in the bottom surface;
a first conduit extending from the top surface and fluidly coupled to the channel;
a second conduit extending substantially radially from the axis and fluidly coupled to the channel; and
a flow regulator within the bottom section, the flow regulator configured to change a flow direction of gas received from the first conduit and gas received from the second conduit.

2. The gas manifold of claim 1, wherein the flow regulator comprises a plurality of fins extending inward from an interior wall of the channel.

3. The gas manifold of claim 2, wherein each fin of the plurality of fins comprises a first section and a second section, wherein the first section comprises an interior angled surface at an angle relative to the axis, and wherein the second section comprises an interior parallel surface substantially parallel the axis, wherein the angle is greater than 0 degrees and less than 90 degrees or between about 15 degrees and about 45 degrees.

4. The gas manifold of claim 3, wherein a ratio of height of the first section relative to a height of the second section is between about 1:20 and about 1:10.

5. The gas manifold of claim 2, wherein the plurality of fins comprises between about 9 and about 18.

6. The gas manifold of claim 2, wherein the plurality of fins are integrally formed within the body.

7. The gas manifold of claim 1, wherein the flow regulator comprises a helical section.

8. The gas manifold of claim 7, wherein the flow regulator further comprises a plate coupled to the helical section.

9. The gas manifold of claim 8, wherein the plate comprises one or more openings spanning a height of the plate.

10. The gas manifold of claim 7, wherein a pitch of a helix of the helical section is between about 4 mm and about 10 mm or between about 5 and about 8 mm

11. The gas manifold of claim 7, wherein the flow regulator is removably inserted within the channel.

12. The gas manifold of claim 1, wherein the flow regulator comprises a plurality of deflectors extending from an interior surface of the channel toward the axis.

13. The gas manifold of claim 12, wherein the plurality of deflectors comprises a first set of deflectors at a first height within the channel and a second set of deflectors at a second height within the channel, the first height different than the second height.

14. The gas manifold of claim 13, wherein deflectors of the first set of deflectors are offset from deflectors of the second set of deflectors.

15. The gas manifold of claim 12, wherein each deflector of the plurality of deflectors comprises a substantially flat surface angled at an angle relative to the axis, wherein the angle is greater than 0 degrees and less than 90 degrees or between about 15 degrees and about 45 degrees.

16. The gas manifold of claim 1, wherein the flow regulator comprises a first body spanning a first cross-section of the channel and comprising a first plurality of holes through the first body.

17. The gas manifold of claim 16, further comprising a second body spanning a second cross section of the channel and comprising a second plurality of holes through the second body.

18. The gas manifold of claim 1, wherein the flow regulator comprises a plate having an opening therethrough, wherein the opening comprises a first exterior section, a second exterior section, and an interior section connecting the first exterior section and the second exterior section, wherein a cross section of the interior section is less than a cross section of the first exterior section and is less than a cross section of the second exterior section.

19. An assembly comprising:
a gas manifold comprising:
a body comprising a top section and a bottom section, the top section comprising a top surface, and the bottom section comprising a bottom surface;
a channel spanning along an axis within the body and between the top section and an opening in the bottom surface;
a first conduit extending from the top surface and fluidly coupled to the channel;
a second conduit extending substantially radially from the axis and fluidly coupled to the channel; and
a flow regulator within the bottom section, the flow regulator configured to change a flow direction of gas received from the first conduit and gas received from the second conduit; and
a gas distribution device fluidly coupled to the gas manifold.

20. A reactor system comprising:
a reaction chamber;
a gas distribution device configured to deliver gas to an interior of the reaction chamber; and
a gas manifold fluidly coupled to the gas distribution device, the gas manifold comprising:
a body comprising a top section and a bottom section, the top section comprising a top surface, and the bottom section comprising a bottom surface;
a channel spanning along an axis within the body and between the top section and an opening in the bottom surface;
a first conduit extending from the top surface and fluidly coupled to the channel;
a second conduit extending substantially radially from the axis and fluidly coupled to the channel; and
a flow regulator within the bottom section, the flow regulator configured to change a flow direction of gas received from the first conduit and gas received from the second conduit.
